(19) United States
(12) Patent Application Publication
(10) Pub. No.: US 2009/0081872 A1
(43) Pub. Date: Mar. 26, 2009

(54) PLASMA ETCHING METHOD FOR ETCHING SAMPLE

(76) Inventors: Hitoshi Kobayashi, Kudamatsu-shi (JP); Masamichi Sakaguchi, Kudamatsu-shi (JP); Koichi Nakaune, Hikari-shi (JP); Masunori Ishihara, Kudamatsu-shi (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/018,836

(22) Filed: Jan. 24, 2008

(30) Foreign Application Priority Data
Sep. 21, 2007 (JP) 2007-244672

(51) Int. Cl. H01L 21/31; H01L 21/3065

(52) U.S. Cl. 438/696; 438/710; 257/E21.218; 257/E21.258

(57) ABSTRACT

The invention provides an etching method having selectivity of a high-K material such as Al₂O₃ to polysilicon or hard mask. The present invention provides a method for manufacturing a semiconductor device by etching, using a plasma etching apparatus, a sample including an interlayer insulating layer 14 formed of a high-K material such as Al₂O₃ of a hard mask 11 and a Poly-Si layer 15 in contact with the interlayer insulating layer, wherein the method includes etching the high-K material 14 using BCl₃, He and HBr while setting a temperature of a sample stage to normal temperature and applying a time-modulated high bias voltage, and repeating said etching process and a deposition process using SiCl₄, BCl₃ and He.

The present application is based on and claims priority of Japanese patent application No. 2007-244672 filed on Sep. 21, 2007, the entire contents of which are hereby incorporated by reference.

### BACKGROUND OF THE INVENTION

1. Field of the Invention

The present invention relates to a plasma etching method for etching samples for forming semiconductor devices including interlayer insulating layers formed for example of Al₂O₃, masks arranged above the interlayer insulating layers, and base layers formed of polysilicon (hereinafter referred to as Poly-Si) in contact with the interlayer insulating layers in a plasma processing apparatus. The plasma etching method includes steps of selectively processing the mask and the base layer.

2. Description of the Related Art

Along with the advance in integration and speed of semiconductor devices, insulating layers disposed between gates, or interlayer insulating layers, are required to have improved permittivity, and high-K materials are starting to be used instead of the conventional SiO₂ layers so as to realize higher permittivity.

Al₂O₃ is mainly used as the high-K material. In particular, Al₂O₃ is used as high-K material to form insulating layers arranged between control gates and floating gates of flash memory devices. The two types of gates are respectively formed of Poly-Si and isolated from each other. In order to manufacture such devices, Poly-Si constituting the base layer and the mask arranged above the Al₂O₃ layer must be selectively etched when etching the Al₂O₃ layer. Alternately, materials such as ZrO₂ and HfO₂ can be used instead of Al₂O₃ as high-K materials for forming the interlayer insulating layer.

With reference to FIG. 1, the outline of the structure of a flash memory device will be described. As illustrated in FIG. 1(a), the flash memory device has a multilayered structure including, from the bottom, a silicon substrate 17 having isolation trenches 18 filled with SiO₂; base insulating layers 16 formed of SiO₂; Poly-Si layers 15 for forming floating gates; an interlayer insulating layer 14 formed of Al₂O₃; a Poly-Si layer 13 for forming control gates; a W (tungsten) silicon layer 12 for forming control gate wires; and a hard mask 11. A cross-sectional view taken at line A-A of FIG. 1(a) is shown as sectional view A of FIG. 1(b), and a cross-sectional view taken at line B-B of FIG. 1A is shown as sectional view B of FIG. 1(c).

Flash memory devices are created by arranging base insulating layers (SiO₂) 16 on a silicon substrate 17 having isolation trenches 18, arranging a Poly-Si layer 15 thereon, etching the Poly-Si layer 15 to reach the upper surfaces of the isolation trenches 18 and the base insulating layers 16 to create floating gates, arranging an interlayer insulating layer 14 formed of Al₂O₃ on the floating gates and the Poly-Si layers 16, arranging thereon a Poly-Si layer 13 for forming control gates and a W silicon 12, and arranging thereon a hard mask 11, before etching the structure to create a wafer, or sample, having flash memory devices or other semiconductor devices arranged on a base insulating layer.

The present invention relates to the art of etching interlayer insulating layers 14 formed of Al₂O₃ as illustrated in sectional view A of FIG. 1(b) and sectional view B of FIG. 1(c).

In sectional view A of FIG. 1(b), the interlayer insulating layer 14 is arranged on the isolation trenches 18. In sectional view B of FIG. 1(c), the interlayer insulating layer 14 is arranged on the floating gate 15 formed of Poly-Si.

Therefore, in order to perform etching as illustrated in sectional view B, the Al₂O₃ and the floating gates formed of Poly-Si must be etched with high selectivity.

On the other hand, it has been disclosed for example in Japanese Patent Application Laid-Open Publication No. 2004-296477, hereinafter referred to as patent document 1, that highly selective etching of Al₂O₃ to SiO₂ requires silicon species.

Furthermore, it has been disclosed for example in Japanese Patent Application Laid-Open Publication No. 2007-35860, hereinafter referred to as patent document 2, to etch Al₂O₃ using a gas mixture containing BCl₃, Ar and CH₄ at high temperature to realize highly selective etching of Al₂O₃ to Poly-Si.

Al₂O₃ is usually etched with gas mainly containing Cl₂ or BCl₃, and the selectivity is improved by using a gas mixture containing Ar and CH₄ or by processing at high temperature.

### SUMMARY OF THE INVENTION

When silicon-based gases are used in the processes disclosed in patent document 1, amount of deposits are increased and the shape of the processed Al₂O₃ will be tapered.

FIG. 2 illustrates the structure of a stepped portion of the flash memory device shown in FIG. 1. FIG. 2 is an explanatory view illustrating, from top to bottom, the change in status with time of the Al₂O₃ etching process of sectional view C taken at line C-C of sectional view A of FIG. 1(b) and sectional view B of FIG. 1(c).

FIG. 2(a) illustrates the structure of a stepped portion when etching has been performed to expose the interlayer insulating layer 14 formed of Al₂O₃. FIG. 2(b) illustrates a state in which the flat area of the interlayer insulating layer 14 is etched to reach the Poly-Si (polysilicon) base layer 16 and the surfaces of the SiO₂ 18 forming the trenches. FIG. 2(c) illustrates a state in which the Al₂O₃ etching for removing the interlayer insulating layer 14 is continuously performed to etch the upper portion of the interlayer insulating layer 14 arranged on the side walls of the Poly-Si layer 15 of the stepped portion. In the Al₂O₃ etching process, the selected Al₂O₃ etching gas should preferably realize high selectivity of Al₂O₃ to Poly-Si and high selectivity of Al₂O₃ to SiO₂. FIG. 2(d) illustrates a state in which the Al₂O₃ etching process of the interlayer insulating layer 14 is completed. When the etching of Al₂O₃ is completed, the interlayer insulating layer 14 should be totally removed, leaving the Poly-Si layer 15 and the SiO₂ 18 forming the trenches.

According to the method disclosed in patent document 2, the process for removing Al₂O₃ from the side walls of the floating gates 15 and the upper portion of the isolation trenches 18 causes a certain amount of the floating gates 15 to be etched, and therefore, even higher selectivity is required. Moreover, a certain amount of the hard mask 11 is also etched, since the selectivity is not sufficiently high. Even higher selectivity is required to remove the Al₂O₃ of the stepped portion. Furthermore, due to high temperature, the control gate wire (WSi) 12 and the Poly-Si layer 13 may be side-etched.

Therefore, it is an object of the present invention to provide an etching method for solving the above-mentioned problems by selectivity etching Al₂O₃ to Poly-Si (polysilicon) or hard mask.

In order to achieve the above object, a plasma etching method for processing samples having semiconductor devices including an interlayer insulating layer formed for example of Al₂O₃, and a polysilicon layer arranged as a base layer of the interlayer insulating layer and a hard mask layer arranged above the interlayer insulating layer according to the present invention includes using a gas mixture containing BCl₃, He and HBr as etching gas for etching the interlayer insulating layer formed for example of Al₂O₃.

Further according to the present invention, either prior to or after etching the interlayer insulating layer, a gas mixture containing BCl₃, He and SiCl₄ is used to stick deposits on the hard mask and the base layer so as to prevent side etch of the hard mask. In the etching process, a time-modulated high frequency (RF) bias voltage may be applied to the sample.

According to the present invention, it becomes possible to stick deposits on the hard mask and the base film by performing discharge using a gas mixture containing BCl₃, He and SiCl₄ prior to etching the interlayer insulating layer formed for example of Al₂O₃, thereby enabling Al₂O₃ to be removed with a sufficient amount of the hard mask remaining.

When silicon-based gases such as SiCl₄ are used to etch Al₂O₃, an increased amount of silicon deposits are deposited on the side walls and upper surfaces of the layer, creating tapered shapes. However, since the present invention includes etching Al₂O₃ using BCl₃, He and HBr, and repeatedly performing SiCl₄ applying processes for sticking silicon deposits on the surface and side walls of the hard mask arranged above the Al₂O₃ layer or on the surface and side walls of the Poly-Si, the selectivity of Al₂O₃ to the Poly-Si layer and the hard mask can be maintained, realizing vertical processing of the Al₂O₃ and preventing side etch of the WSi layer arranged above the Al₂O₃ layer.

Further, the processes of the present invention can be performed at normal temperature, that is, 20° C.

### BRIEF DESCRIPTION OF THE DRAWINGS

FIG. 1 is a cross-sectional view illustrating the structure of a flash memory device including Al₂O₃;

FIG. 2 is an explanatory view illustrating the processing steps according to the present invention;

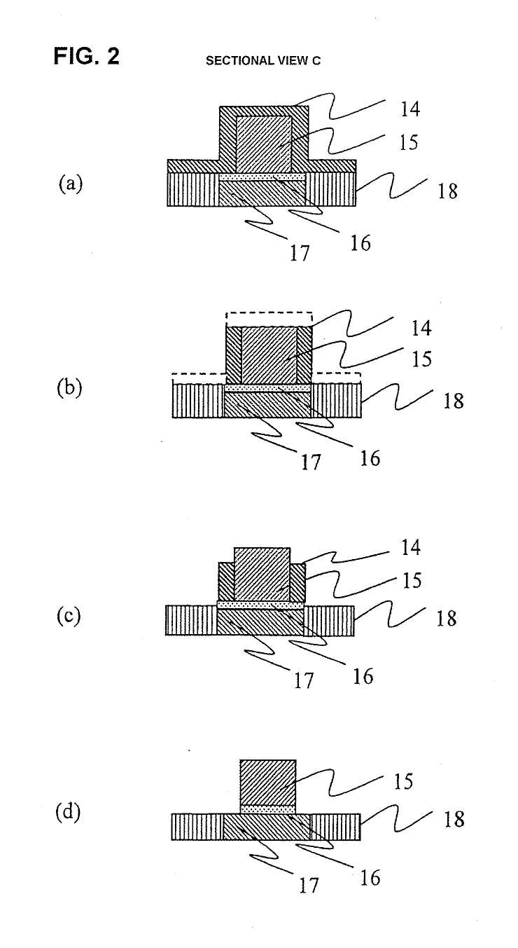

FIG. 3 is an explanatory view showing the basic structure of a plasma etching apparatus to which the present invention is applied; and

FIG. 4 is an explanatory view illustrating the processing method according to the present invention.

### DETAILED DESCRIPTION OF THE PREFERRED EMBODIMENTS

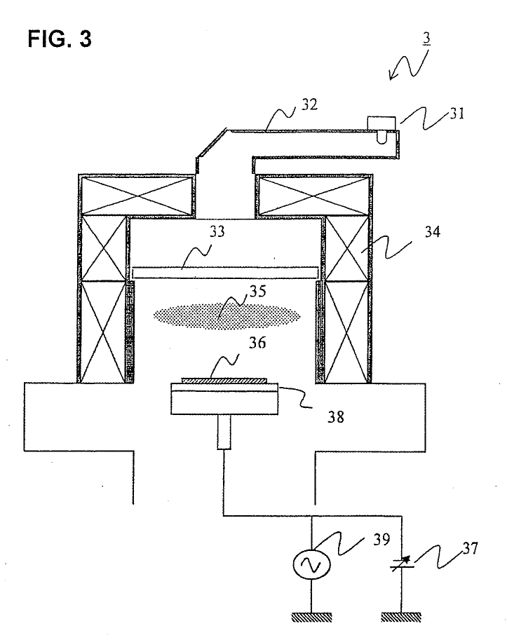

The plasma etching method for etching a sample according to the present invention will now be described. An example of the arrangement of a plasma processing apparatus used for the plasma etching method for etching a sample according to the present invention will be described with reference to FIG. 3. This embodiment is described using a microwave plasma processing apparatus that utilizes microwaves and a magnetic field as means for generating plasma. According to this embodiment, a plasma processing apparatus 3 includes a magnetron 31, a waveguide 32, a shower plate 33 formed of a quartz plate, a solenoid coil 34, an electrostatic chuck power supply 37, a sample stage 38 and a high-frequency bias power supply (high-frequency power supply) 39. A wafer or sample 36 to be processed is placed on the sample stage 38 and subjected to plasma etching in plasma 35 generated in a processing chamber.

Microwaves generated via the magnetron 31 are guided through the waveguide 32, passed through the shower plate 33 formed of a quartz plate and irradiated to the interior of a vacuum reactor of the plasma processing apparatus. Processing gases are supplied from a gas supply unit not shown via the shower plate into the processing chamber within the vacuum reactor formed below the shower plate 33 formed of a quartz plate. A solenoid coil 34 is arranged surrounding the vacuum reactor, and electron cyclotron resonance (ECR) is induced by the magnetic field generated by the solenoid coil and the microwaves supplied to the chamber. Thereby, processing gases are turned into high density plasma 35 with high efficiency. Direct current voltage is applied from the electrostatic chuck power supply 37 to the sample stage 38, by which the wafer 36 to be processed is attracted onto the electrode or sample stage via electrostatic chucking force. Further, an RF bias power supply 39 is connected to the electrode or sample stage 38 for supplying high frequency power to the wafer 36 chucked onto the electrode 38, applying accelerating voltages to ions present in the plasma 35 such that the ions are accelerated perpendicularly toward the wafer. After the etching process, the processing gases are evacuated through an evacuation port arranged at the lower portion of the apparatus via a turbo-pump/dry pump not shown.

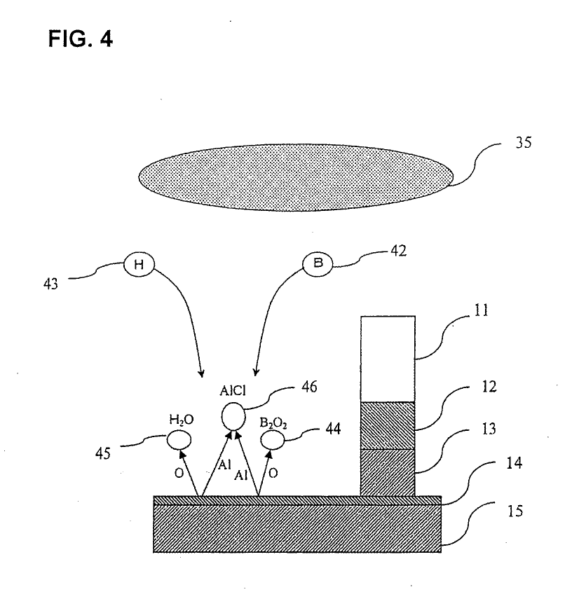

With reference to FIG. 4, the plasma etching method for etching a sample according to the present embodiment using the plasma processing apparatus of FIG. 3 will now be described. The etching conditions according to the present embodiment are shown in Table 1.

In FIG. 4, the semiconductor device formed on the sample includes, from the top layer in the named order, a patterned hard mask 11; a tungsten silicon (WSi) layer 12 for forming control gate wires; a Poly-Si layer 13 for forming control gates; an interlayer insulating layer (Al₂O₃) 14; and a Poly-Si layer 15 for forming floating gates. FIG. 4 illustrates in simplified form the bonding state of Al₂O₃ during etching.

Etching is performed using plasma 35 generated from a processing gas composed of a gas mixture of BCl₃, He and HBr to etch Al₂O₃ 14 arranged below the already-processed W silicon 12 and the Poly-Si layer 13. The B 42 from BCl₃ turned into plasma dissociates the Al-O bond of the Al₂O₃, and bonds with o to generate B₂O₂ 44. Further, the H 43 from HBr turned into plasma dissociates the Al-O bond of the Al₂O₃, and bonds with the dissociated O to generate H₂O 45. The Al dissociated from Al₂O₃ bonds with Cl to generate AlCl 46. The bonded B₂O₂44, H₂O 45 and AlCl 46 are either evacuated from the etching apparatus or deposited as deposits for example on the wide walls of the etching apparatus. The etching of Al₂O₃ is performed in this manner.

TABLE 1

| | Gas flow rate (mL/min) | | | | Pressure | Microwave | power | |
|---|---|---|---|---|---|---|---|---|
| Step | HBr | He | SiCl₄ | BCl₃ | (Pa) | (W) | (W) | Temp. (° C.) |
| 1 | 0 | 80 | 20 | 60 | 0.2 | 800 | 0 | 20 |
| 2 | 10 | 110 | 0 | 40 | 0.2 | 1400 | 400 | 20 |
| | | | | | | | (time- | |
| | | | | | | | modulated) | |

The etching conditions of table 1 are used to describe the plasma etching process of the interlayer insulating layer (Al₂O₃) 14. The plasma etching process of Al₂O₃ 14 according to the present invention includes two steps, step 1 and step 2. Step 1 utilizes a gas mixture of BCl₃, SiCl₄ and He with a ratio of 60:20:80, a pressure of 0.2 Pa and microwaves of 800 W, and the temperature of the processing wafer is set to 20° C., with no high frequency bias voltage applied. This process is for depositing silicon-based deposits on the upper surface and side walls of the hard mask 11 and the side walls of the WSi 12 and Poly-Si 13 to thereby suppress etching of the hard mask.

Step 2 is for etching Al₂O₃ using plasma while continuing the discharge of step 1, wherein step 2 utilizes a gas mixture of HBr, BCl₃ and He with a ratio of 10:40:110, a pressure of 0.2 Pa and microwaves of 1400 W, and the temperature of the processing wafer is set to 20° C., wherein time-modulated RF bias voltage of 400 W is applied.

In order to realize high selectivity of Al₂O₃ to the mask, the etching rate of Al₂O₃ must be high, and deposits must be formed to cover only the mask. Therefore, it is effective from the viewpoint of slowing down the etching of the hard mask, that is, to improve the selectivity of Al₂O₃, by utilizing the characteristic feature that the etching rate of Al₂O₃ is increased when silicon species are present, by adding SiCl₄ to the etching gas composed of BCl₃ and H₃ to form deposits on the hard mask 11 and the side walls when etching Al₂O₃.

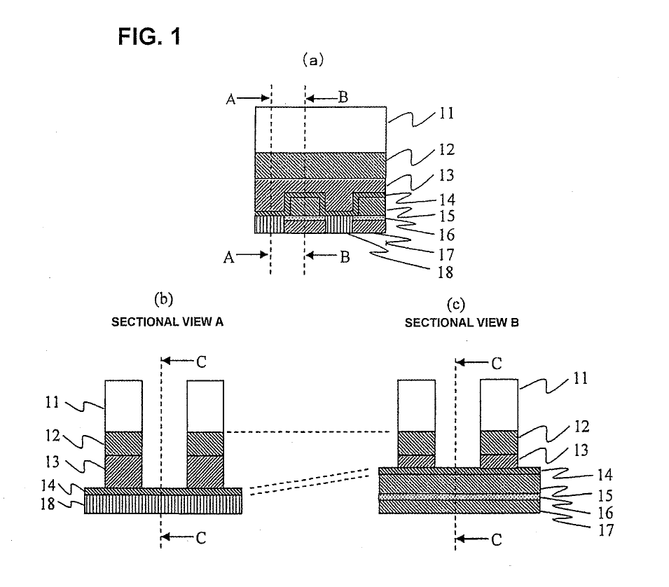

Since Al₂O₃ is thick at the stepped portion, sufficient over-etching is required to etch the Al₂O₃ at the stepped portion. At this time, it is necessary to prevent side etch of the W silicon 12 and Poly-Si layer 13, to improve the Al₂O₃/Poly-Si selectivity of Al₂O₃ 14 to the Poly-Si 15 forming the floating gates arranged below Al₂O₃ 14 (FIG. 1), and to improve the Al₂O₃/mask selectivity of Al₂O₃ to the mask arranged above the Al₂O₃ in order to etch the floating gates under the mask with a sufficient amount of the mask remaining.

Thus, the side etch of the W silicon 12 and the Poly-Si 13 is prevented and the selectivity of Al₂O₃ to mask is improved by applying a time-modulated high-frequency bias voltage to the sample during etching of Al₂O₃ in step 2. By applying time-modulated high-frequency bias voltage to the sample, Al₂O₃ is etched when high-frequency bias voltage is applied, and deposits are generated when high-frequency bias voltage is not applied.

The conditions for time-modulating the high-frequency bias voltage are as follows: a bias frequency of 400 KHz, an output of 400 W, an application time of 5×10⁻⁴ seconds, and a non-application time of 5×10⁻⁴ seconds.

The selectivity of Al₂O₃ to Poly-Si can be improved by repeating the silicon-based deposition process of step 1 using SiCl₄, BCl₃and He during which deposits are formed and the etching process of step 2 for etching Al₂O₃ using HBr, BCl₃ and He, by which etching of the Poly-Si layer 15 arranged under the Al₂O₃ layer 14 is suppressed.

As described above, the present invention provides a method for etching a sample having semiconductor devices by etching, using a plasma processing apparatus, a sample including a base layer formed for example of Poly-Si in contact with an interlayer insulating layer formed for example of Al₂O₃, wherein the method includes etching the interlayer insulating layer using a gas containing BCl₃, He and HBr.

The present invention provides a method for etching a sample having semiconductor devices by etching, using a plasma processing apparatus, a sample including a base layer formed for example of Poly-Si in contact with an interlayer insulating layer formed for example of Al₂O₃, wherein the method includes etching the interlayer insulating layer using a processing gas containing BCl₃, He and HBr, and further providing a process of sticking deposits on a mask and a base layer in contact with the interlayer insulating layer using a processing gas including Si-containing gas.

The present invention also provides a method for etching a sample having semiconductor devices by etching, using a plasma processing apparatus, a sample including a base layer formed for example of Poly-Si in contact with an interlayer insulating layer formed for example of Al₂O₃, wherein the method includes repeating the process of etching the interlayer insulating layer using a processing gas containing BCl₃, He and HBr, and the process of sticking deposits on a mask and a base layer in contact with the interlayer insulating layer using a processing gas including Si-containing gas.

Further, the present invention provides a method for etching a sample having semiconductor devices by etching, using a plasma processing apparatus, a sample including a base layer formed for example of Poly-Si in contact with an interlayer insulating layer formed for example of Al₂O₃, wherein the method includes etching the interlayer insulating layer while applying time-modulated high-frequency bias voltage to the sample.

1. A plasma etching method for etching, using a plasma processing apparatus, a sample having a semiconductor device including a base layer in contact with an interlayer insulating layer; the method comprising
a plasma etching process of etching the interlayer insulating layer using a processing gas containing BCl₃, He and HBr.

2. The plasma etching method for etching a sample according to claim 1, further comprising
a plasma process for sticking deposits on a mask arranged above the interlayer insulating layer and a base layer in contact with the interlayer insulating layer using a processing gas containing Si.

3. The plasma etching method for etching a sample according to claim 1, further comprising
alternately performing a process for plasma etching the interlayer insulating layer using a processing gas containing BCl₃, He and HBr, and a plasma process for sticking deposits on a mask arranged above the interlayer insulating layer and a base layer in contact with the interlayer insulating layer using a processing gas containing Si.

4. The plasma etching method for etching a sample according to claim 1, wherein high-frequency bias voltage is applied to the sample, and time-modulated high-frequency bias voltage is applied to the sample during the plasma etching process for etching the interlayer insulating layer.
